(19) United States
(12) Patent Application Publication
(10) Pub. No.: US 2011/0277814 A1
(43) Pub. Date: Nov. 17, 2011

(54) Solar Cell Module and Method of Manufacturing Same

(75) Inventors: Takeshi Kyoda, Higashiomi-shi (JP); Tetsuo Niwa, Higashiomi-shi (JP)

(73) Assignee: KYOCERA CORPORATION, Kyoto-shi, Kyoto (JP)

(21) Appl. No.: 13/145,771

(22) PCT Filed: Jan. 29, 2010
(86) PCT No.: PCT/JP2010/051292

§ 371 Date: Jul. 21, 2011

(30) Foreign Application Priority Data
Jan. 29, 2009 (JP) 2009-018414

(51) Int. Cl. H01L 31/05; H01L 31/18

(52) U.S. Cl. 136/244; 438/98; 257/E31.032

(57) ABSTRACT

Disclosed is a solar cell module wherein the stresses exerted on a solar cell module are relaxed. Specifically, disclosed is a solar cell module which comprises: a plurality of solar cell elements each including a light receiving surface and a rear surface positioned on a reverse side oppositely away from the light receiving surface; and leads connecting one of the solar cell elements and another adjacent solar cell element and including a connection portion connected to one surface of the one solar cell element. At least one of the solar cell elements has a wavy shape in a lengthwise direction of the connection portion.

### TECHNICAL FIELD

The present invention relates to a solar cell module and a method of manufacturing the solar cell module.

### BACKGROUND ART

Recently, widespread use of solar cell modules has been encouraged from the viewpoint of environmental protection. In general, a solar cell module is constructed by successively stacking, from a light receiving surface side, a light-transmissive base plate, a solar cell element row (solar cell string) protected by a sheet-like filling material made of, e.g., a transparent thermosetting resin and surrounding the solar cell string, and a rear-surface protective member protecting a rear surface of the solar cell module, thus forming an integral multilayer structure. As a solar cell element, a silicon-containing element is particularly used in many cases because of having higher photovoltaic efficiency. The solar cell string is formed by connecting electrodes on one solar cell element and electrodes on another adjacent solar cell element through leads using solders, and by establishing electrical connection therebetween.

However, when the solders are cooled after connecting the electrodes as described above, the solar cell elements are often warped due to thermal stresses caused by the difference in coefficient of thermal expansion between the solar cell elements and the leads. Particularly, in the case of a solar cell string in which principal surfaces of the adjacent solar cell elements on the same side, e.g., non-light-receiving surfaces thereof, are connected through leads and no leads are present on the light receiving surface side, the solar cell elements tend to warp convexly on the light receiving surface side as viewed in a cross-section taken in an array direction of the solar cell elements. When a solar cell module is constructed by using the solar cell string including the warped solar cell elements, stresses are applied to connected (joint) portions between the solar cell elements and the leads, whereby the connected portions may crack or break. This arouses a possibility that output power of the solar cell module may be reduced.

Japanese Unexamined Patent Application Publication No. 2007-250623 proposes a method of locally reducing a cross-sectional area of a lead, thereby relaxing thermal stresses and lessening a warp. However, the warp cannot be sufficiently lessened by the proposed method when the leads are disposed only on the principal surfaces of the solar cell element on the same side.

### SUMMARY OF INVENTION

The present invention has been made in view of the problems described above, and an object of the present invention is to provide a solar cell module in which stresses exerted on a solar cell string are relaxed, and a method of manufacturing the solar cell module.

The present invention provides a solar cell module comprising a plurality of solar cell elements each including a light receiving surface and a rear surface positioned on a reverse side oppositely away from the light receiving surface, and a plurality of leads electrically connecting adjacent two of the solar cell elements, wherein at least one of the solar cell elements has a wavy shape in a lengthwise direction of the leads.

With the solar cell module according to the present invention, stresses exerted on connected portions between the solar cell elements and the leads are relaxed, whereby not only the occurrence of cracks and breakage in the connected portions, but also reduction in output power of the solar cell module are satisfactorily reduced. Further, even when the leads are extended and contracted with thermal expansion and thermal contraction, for example, on condition that the leads have a larger coefficient of thermal expansion than the solar cell elements, the solar cell elements are deformable following the extension and the contraction of the leads. As a result, stresses generated between the leads and the solar cell elements are relaxed.

Also, the present invention provides a method of manufacturing a solar cell module, the method comprising a first step of electrically connecting, by leads, adjacent two among a plurality of solar cell elements each including a light receiving surface and a rear surface on a reverse side oppositely away from the light receiving surface, and a second step of applying a deformation force to act on each of the solar cell elements and projecting a partial region of each solar cell element on a lead side.

With the method of manufacturing the solar cell module according to the present invention, since the solar cell module is constituted by using a solar cell string that has been flattened in the second step, the occurrence of chipping, etc. in a manufacturing process is satisfactorily reduced. Further, alignment accuracy in a widthwise direction of the solar cell string is ensured, and a variation in array of the solar cell elements within the solar cell module is reduced, thus improving an aesthetic impression in design of the solar cell module. Moreover, in the solar cell module thus obtained, stresses exerted on the connected portions between the solar cell elements and the leads are relaxed, whereby not only the occurrence of cracks and breakage in the connected portions, but also reduction in output power are satisfactorily reduced.

### BRIEF DESCRIPTION OF DRAWINGS

FIG. 1 is a sectional view illustrating one example of a solar cell module.

FIG. 2 illustrates one example of a solar cell element having a metal wrap through structure; specifically,

FIG. 2(a) is a perspective view illustrating a second principal surface (light receiving surface side) of the solar cell element, and

FIG. 2(b) is a perspective view illustrating a first principal surface (non-light-receiving surface side) of the solar cell element.

FIG. 3 is a perspective view illustrating one example of a solar cell string.

FIG. 4 is a sectional view illustrating a solar cell module using the solar cell string of FIG. 3.

FIG. 5 is a perspective view illustrating, as a comparative example, a solar cell string in which solar cell elements tend warp convexly on the second principal surface side.

FIG. 6 is a sectional view illustrating a solar cell module using the solar cell string of FIG. 5.

FIG. 7 illustrates a process of manufacturing a solar cell string by connecting the solar cell elements and leads; specifically, FIG. 7(a) is a perspective view illustrating a state before the connection, looking from the first principal surface side (non-light-receiving surface side), and FIG. 7(b) is a perspective view illustrating a state after the connection, looking from the second principal surface side (light receiving surface side).

FIG. 8 illustrates a first manufacturing method for a solar cell module; specifically, FIG. 8(a) is a side view illustrating a state before bending stresses with three-point bending are applied to a solar cell string, FIG. 8(b) is a side view illustrating a state where the bending stresses are applied to the solar cell string, and FIG. 8(c) illustrates a model representing stresses generated in a portion A in FIG. 8(b) when the bending stresses are applied to the solar cell string.

FIG. 9 illustrates, as an enlarged sectional view, one example of a solar cell module according to the present invention; specifically, FIG. 9(a) is a sectional view illustrating the state before the bending stresses are applied to a solar cell string, FIG. 9(b) is a sectional view illustrating the state where the bending stresses are applied to the solar cell string, and FIG. 9(c) illustrates a model representing forces generated when the bending stresses are applied to the solar cell string.

FIG. 10 illustrates a second manufacturing method for a solar cell module; specifically, FIG. 10(a) is a side view illustrating a state before pressing, FIG. 10(b) is a side view illustrating a state during the pressing, FIG. 10(c) is a side view illustrating a state after the pressing, and FIG. 10(d) illustrates one example of a support member 71.

FIG. 11 plots the bending stresses applied to the solar cell string and tensile stresses applied to the lead in the first and second manufacturing methods for the solar cell module; specifically, FIG. 11(a) is a chart plotting the bending stress in the second manufacturing method, FIG. 11(b) is a chart plotting the tensile stress in the second manufacturing method, FIG. 11(c) is a chart plotting the bending stress in the first manufacturing method, and FIG. 11(d) is a chart plotting the tensile stress in the first manufacturing method.

FIG. 12 illustrates a third manufacturing method for a solar cell module; specifically, FIG. 12(a) is a side view illustrating a state before pressing of a solar cell string, FIG. 12(b) is a side view illustrating a state where individual solar cell elements are pressed until the solar cell string becomes flat, FIG. 12(c) is a side view illustrating a state where bending stresses are applied until a first principal surface 5a is pressed and deformed into a convex shape, and FIG. 12(d) is a side view illustrating a state after the pressing of the solar cell string.

FIG. 13 illustrates a fourth manufacturing method for a solar cell module; specifically, FIG. 13(a) is a side view illustrating a state before pressing of a solar cell string, FIG. 13(b) is a side view illustrating a state where a solar cell element at a leftmost end is pressed and bending stresses are applied thereto, and FIG. 13(c) is a side view illustrating a state where the pressing of the solar cell element at the leftmost end is stopped, and where the solar cell element adjacent to the leftmost solar cell element is pressed and bending stresses are applied thereto.

FIG. 14 illustrates a fifth manufacturing method for a solar cell module; specifically, FIG. 14(a) is a side view illustrating a state before pressing of a solar cell string, FIG. 14(b) is a side view illustrating a state where the solar cell string is pressed until it becomes flat, FIG. 14(c) is a side view illustrating a state where the solar cell string is pressed until it becomes convex on the second principal surface side, and FIG. 14(d) is a side view illustrate a state after the pressing of the solar cell string.

FIG. 15 illustrates a first modification of the manufacturing method for the solar cell module; specifically, FIG. 15(a) is a side view illustrating a state before pressing of the solar cell string, and FIG. 15(b) is a side view illustrating a state where the solar cell string is pressed and bending stresses are applied to the solar cell string.

FIG. 16 illustrates a second modification of the manufacturing method for the solar cell module; specifically, FIGS. 16(a), 16(b), and 16(c) are side views illustrating the progress of a process of conveying the solar cell string, while the solar cell string is pressed by a support roller and a pressing roller and bending stresses are applied thereto, and FIG. 16(d) is a chart plotting tensile stress and representing change over time of the tensile stress that is applied to the lead of the solar cell string during the conveying.

### DESCRIPTION OF EMBODIMENTS

A solar cell module and a method of manufacturing the solar cell module, according to the present invention, will be described below with reference to the accompanying drawings. In some of the drawings, a right-handed xyz-coordinate system is attached on the premise that an array direction of solar cell elements in the solar cell string is an x-axis direction, and that a stacking direction in the solar cell module (i.e., a direction toward the non-light-receiving surface side from the light receiving surface side of the solar cell element) is a z-axis direction.

(Solar Cell Module)

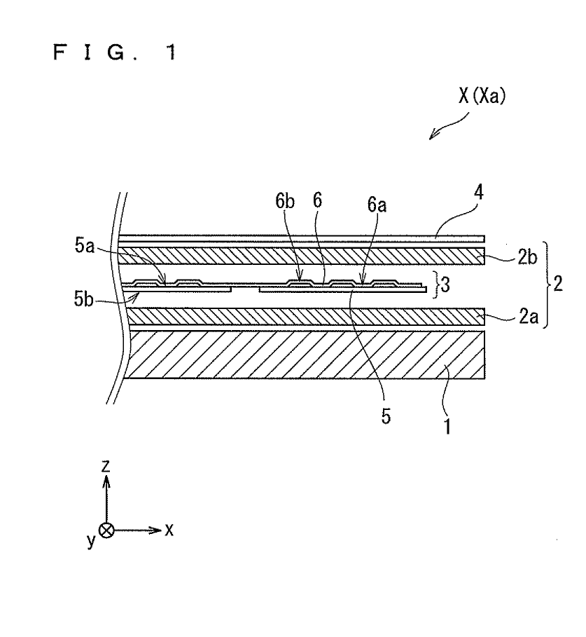

A solar cell module X according to an embodiment has a structure that is obtained, as illustrated in FIG. 1, by successively stacking, a light-transmissive base plate 1, a filling material 2a on the light receiving surface side, a solar cell element row (solar cell string) 3, a filling material 2b on the non-light-receiving surface side, and a rear-surface protective member 4. The solar cell string 3 includes a plurality of solar cell elements 5, which are electrically connected in series by leads 6. In the following description, the filling material 2a on the light receiving surface side and the filling material 2b on the non-light-receiving surface side are collectively called a “filling material 2”.

Materials of the light-transmissive base plate 1 are not particularly limited insofar as the material allows light to enter the solar cell elements 5. The light-transmissive base plate 1 can be provided as a base plate having high light transmittance and made of, e.g., glass such as white glass, tempered glass, double tempered glass or heat reflecting glass, or a polycarbonate resin. For example, a plate of white tempered glass with a thickness of about 3 mm to 5 mm or a synthetic resin plate (made of, e.g., a polycarbonate resin) with a thickness of about 5 mm is preferably used as the light-transmissive base plate 1.

The filling material 2 serves to seal off the solar cell elements 5. The filling material 2 is made of, e.g., an organic compound containing, as a main component, an ethylene—vinyl acetate copolymer (EVA) or polyvinyl butyral (PVB). More specifically, the filling material 2 is prepared by shaping the organic compound into a sheet with a thickness of about 0.4 to 1 mm by using a T-die and an extruder, and by cutting the sheet in an appropriate size. The filling material 2 contains a cross-linking agent. The cross-linking agent serves to link molecules of, e.g., EVA. The cross-linking agent can be provided, for example, as an organic peroxide that is decomposed at temperatures of 70° C. to 180° C. and generates a radial. Examples of the organic peroxide include 2,5-dimethyl-2,5-bis(t-butylperoxy)hexane and tert-hexyl peroxypivalate. When EVA is used as the filling material 2, the cross-linking agent is preferably contained at a rate of about 1 part by mass with respect to 100 parts by mass of EVA. Other types of resins than the above-mentioned EVA and PVB can also be preferably used as the filling material 2 insofar as they are each a thermosetting resin or a resin that is given with a thermosetting characteristic by adding the cross-linking agent to a thermoplastic resin. For example, an acryl resin, a silicone resin, an epoxy resin, or EEA (ethylene—ethyl acrylate copolymer) can be used as the filling material 2.

The rear-surface protective member 4 serves to protect the filling material 2 and the solar cell elements 5. The rear-surface protective member 4 can be made of PVF (polyvinyl fluoride), PET (polyethylene terephthalate), PEN (polyethylene naphthalate), or a material formed by stacking two or more sheets of them.

The solar cell elements 5 are each preferably of the back contact type having, e.g., a metal wrap through structure or an emitter wrap through structure. This embodiment is described, by way of example, in connection with the case using the solar cell element 5 of the metal wrap through structure. A rear surface of the solar cell element 5 on the reverse side oppositely away from its light receiving surface is denoted by 5a, and the light receiving surface is denoted by 5b.

The solar cell element 5 is formed of a single-crystal silicon substrate or a polycrystalline silicon substrate in which is formed a PN junction made up of a P-layer containing a larger amount of P-type impurities, e.g., boron, and an N-layer containing a larger amount of N-type impurities, e.g., phosphorous. Electrodes made of, e.g., silver or aluminum, are arranged on the rear surface 5a and/or the light receiving surface 5b of the silicon substrate.

The single-crystal silicon substrate or the polycrystalline silicon substrate is provided, for example, as a rectangular plate having a thickness of about 0.1 mm to 0.3 mm and a size of about 150 mm to 160 mm square, which is cut from an ingot by slicing it. Such a silicon substrate can be formed by using a silicon material with purity of 6N to 11N. Further, the electrodes are formed by screen printing using a conductive paste, e.g., a silver paste or an Al paste.

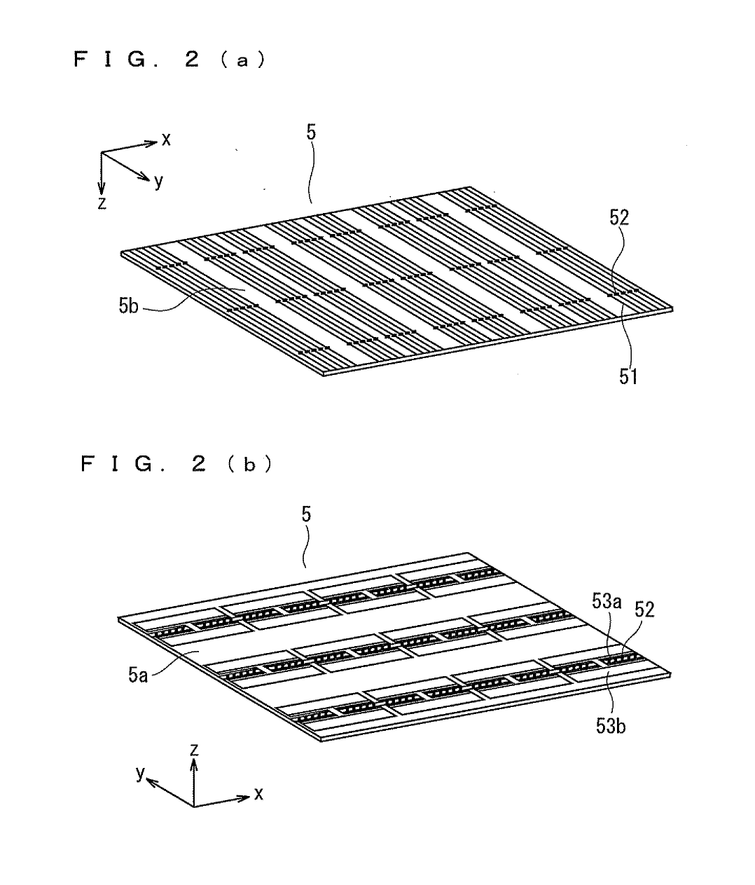

In the solar cell element 5 illustrated in FIGS. 2(a) and 2(b), thin collector electrodes 51, called fingers, are disposed on the light receiving surface 5b. Through-holes 52 filled with an electrode material are formed through the solar cell element 5 and introduce carries generated in the light receiving surface 5b to the rear surface 5a. Further, positive and negative output electrodes 53 (positive output electrodes 53a and negative output electrodes 53b) for outputting electric power are disposed on the rear surface 5a. In the solar cell element 5 illustrated in FIG. 2(b), an array of the positive output electrodes 53a and an array of the negative output electrodes 53b are alternately disposed parallel to a side of the solar cell elements 5.

When bus bar electrodes are not disposed on the light receiving surface 5b as in the solar cell element 5 illustrated in FIGS. 2(a) and 2(b), an effective light receiving area of the solar cell element 5 is increased and hence active area conversion efficiency is increased.

Each of the leads 6 connects output electrodes, having different polarities, of two adjacent solar cell elements 5 in the solar cell string 3. In other words, the lead 6 is disposed to connect the output electrode 53a of one of the two adjacent solar cell elements 5 and the output electrode 53b of the other of the two adjacent solar cell elements 5. Also, when the positive output electrode 53a and the negative output electrode 53b are disposed at plural locations on one solar cell element 5 as illustrated in FIG. 2(b), the lead is connected at each of the plural locations.

The lead 6 may have a uniform elongate shape not including recessed and/or projected portions. Alternatively, as illustrated in FIG. 1, the lead 6 may have a concave portion (connection portion) 6a, of which bottom is connected to the rear surface 5a of the solar cell element 5, and a convex portion (non-connection portion) 6b that is not connected to the rear surface 5a. In the latter case, thermal processes acting on the solar cell string 3 are released in the convex portion 6b, and hence warping of the solar cell string 3 is reduced.

Be it noted that FIG. 1 illustrates a solar cell module X in which the solar cell elements 5 of the solar cell string 3 are each entirely flat in the horizontal direction when viewed on the drawing, i.e., in the array direction of the solar cell elements 5, and the lead 6 is extended in the array direction along the solar cell element 5 (solar cell module in such a flat state is also called a “solar cell module Xa”).

Embodiments of the present invention will be described below.

The solar cell module includes a plurality of solar cell elements 5 each including a light receiving surface and a rear surface positioned on the reverse side oppositely away from the light receiving surface, and leads connecting one of the solar cell element and another adjacent solar cell element and including connection portions connected to one surface of the one solar cell element. At least one of the solar cell elements 5 has a wavy shape in a lengthwise direction of the connection portions.

When the solar cell element 5 is wavy along the array direction thereof, the solar cell element 5 may have a plurality of concave-convex portions along the array direction, a plurality of extreme points, or a specifically periodic or aperiodic curves shape along the array direction. Herein, the term “extreme point” at which a magnitude of the wavy shape is maximum or minimum when the solar cell element 5 is viewed in a cross-section from a direction perpendicular to the array direction. Further, the curved shape may include a triangular wave shape or a rectangular wave shape insofar as the solar cell element 5 performs its function.

The lengthwise direction of the connection portion represents a direction in which the distance from one end to the other end of a connection surface of the connection portion is maximized.

The solar cell module is suitable for the case where adjacent two among the solar cell elements are electrically connected at their rear surfaces by the leads. The reason is that, for example, when the leads 6 are connected to the rear surface 5a as in the solar cell module of back contact type, warping occurs convexly on one surface side.

Further, in the solar cell module, the wavy shape preferably includes a first projected portion 5c projecting on the rear surface side of the first solar cell element.

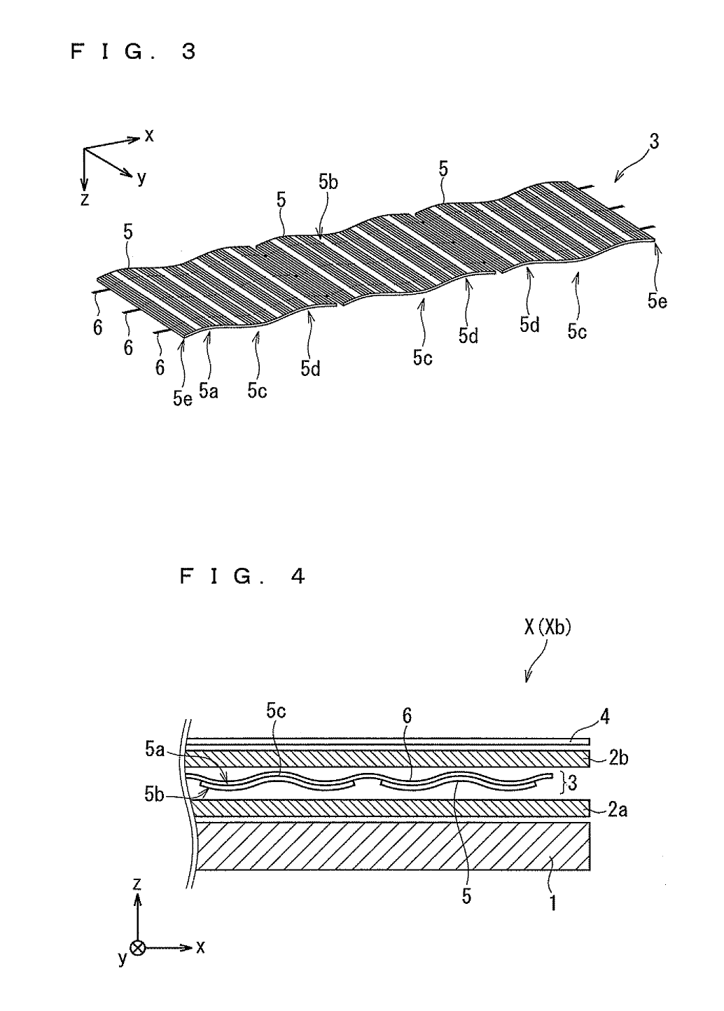

As one example, the solar cell element 5 includes projected portions in at least two positions on the side defining the light receiving surface 5b. As illustrated in FIGS. 3 and 4, for example, the solar cell module X may be constructed such that, when the solar cell string 3 is viewed in a cross-section from a direction perpendicular to the array direction of the solar cell elements 5, the first projected portion 5c of each solar cell element 5 is convexly formed on the side defining the rear surface 5a and the leads 6 are arranged following the convex form (solar cell module in such a state is called a “solar cell module Xb”).

In the solar cell module, preferably, the wavy shape includes a plurality of second projected portions projecting on the light receiving surface side.

In that case, two regions on both sides of the first projected portion 5c projecting on the side defining the rear surface 5a are projected on the side defining the light receiving surface 5b and provide the second projected portions 5d.

In the solar cell module, preferably, the second projected portions are projected on the light receiving surface side farther away from both end portions of the first solar cell element.

In that case, because the second projected portions 5d projecting on the side defining the light receiving surface 5b are not flush with the both end portions 5e, the second projected portions 5d can provide the extreme points.

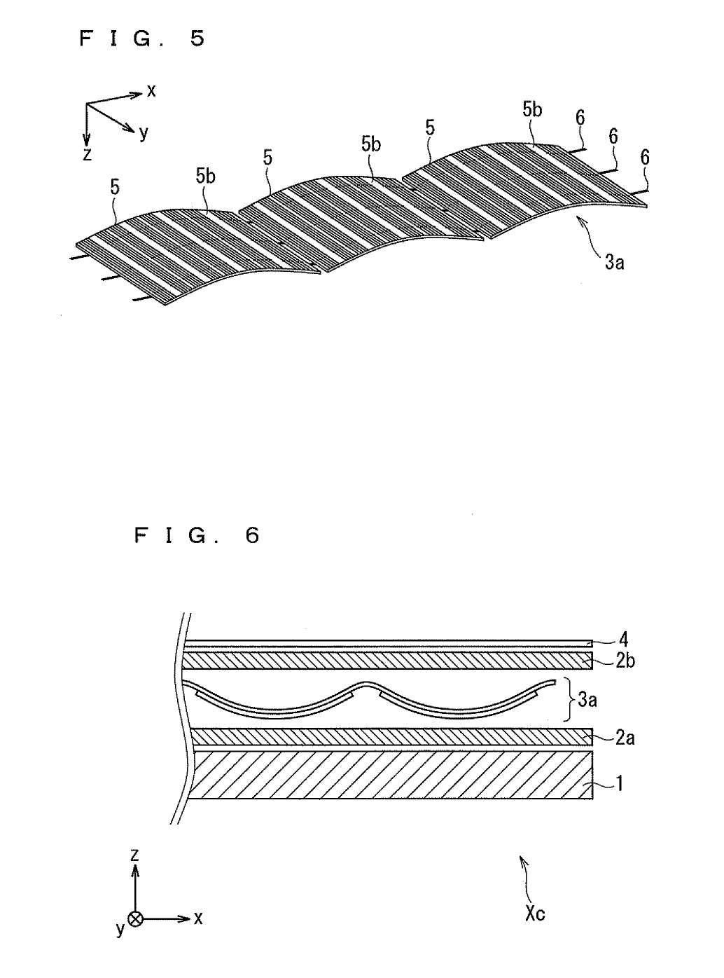

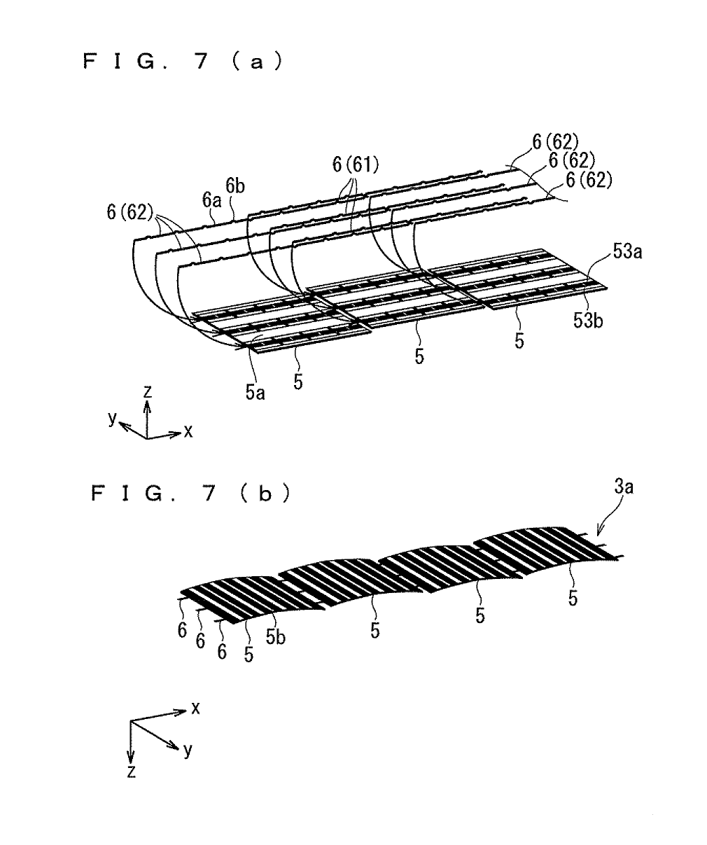

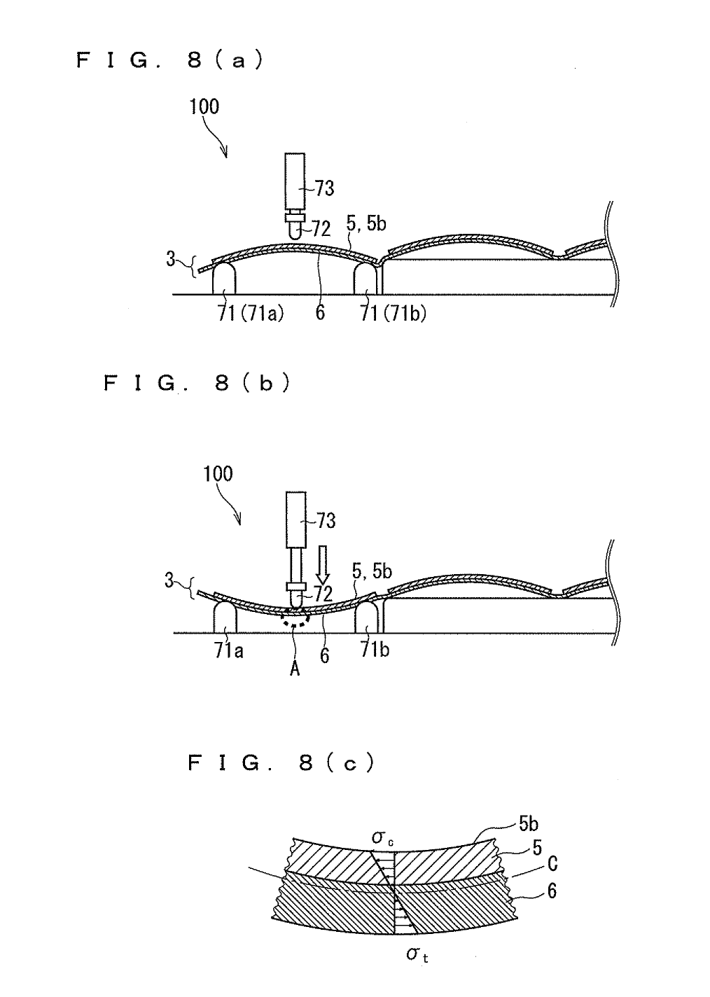

For comparison, FIGS. 5 and 6 illustrate respectively a solar cell string 3a in which each solar cell element 5 is warped and the side defining the light receiving surface 5b becomes convex, and a solar cell module Xc using the solar cell string 3a. In the solar cell string 3a, when the solar cell string 3a is viewed in a cross-section from a direction perpendicular to the array direction of the solar cell elements 5, each solar cell element 5 is uniformly curved to be convex on the side defining the light receiving surface 5b. A floating distance of the solar cell element 5 from a horizontal plane is about 5 mm.

Comparing the solar cell string 3a used in the solar cell module Xc with the solar cell string 3 used in each of the solar cell modules Xa and Xb illustrated in FIGS. 1 and 4, the solar cell string 3 is flatter in the array direction of the solar cell elements 5. In the solar cell module Xc, because the solar cell element 5 is sandwiched between the light-transmissive 1 and the rear-surface protective member 4, etc., a force tending to extend the solar cell element 5 to be flat in the array direction is continuously exerted on the solar cell element 5. Thus, stresses act on the connected portion between the solar cell element 5 and the lead 6 for a long time. This arouses a possibility that a solder at the connected portion may be gradually deformed due to a creep phenomenon, whereby the connected portion may crack or break and hence output power of the solar cell module Xc may be reduced. In contrast, in the solar cell modules Xa and Xb, since the solar cell module 3 is flatter, stresses exerted on the connected portion between the solar cell element 5 and the lead 6 are relaxed. As a result, the occurrence of cracks or breakage at the connected portion and reduction in the output power of the solar cell module X is satisfactorily reduced.

From the viewpoint of relaxing stresses, the solar cell module Xb illustrated in FIG. 4 is more preferable than the solar cell module Xa illustrated in FIG. 1. In the case of the solar cell string 3 having a wavy shape as in the solar cell module Xb, even when the lead 6 having a larger coefficient of thermal expansion than the solar cell element 5 formed of a silicon substrate is extended and contracted due to thermal expansion and contraction, the solar cell element 5 is able to deform following the extension and the contraction of the lead 6, and stresses generated between the lead 6 and the solar cell element 5 are relaxed. Thus, the solar cell module Xb is superior in resistance against heat cycles. On the other hand, when the solar cell element 5 is entirely flat as in the solar cell module Xa illustrated in FIG. 1, the solar cell element 5 cannot follow the extension and the contraction of the lead 6. This arouses a risk that the lead 6 may be peeled off from the solar cell element 5. A floating distance of the solar cell element 5 from a horizontal plane in the solar cell string 3 for use in the solar cell module Xa is preferably about 1 mm.

In the solar cell module, preferably, the leads include at least one first lead and at least one second lead exhibiting polarity that is opposite to polarity of the at least one first lead with respect to each solar cell element.

In the solar cell module, preferably, the at least one first lead and the at least one second lead are parallel to each other.

With such an arrangement, the magnitudes of warps can be made evener and the warps can be caused to occur in a specific direction.

In the solar cell module, preferably, at least one of the at least one first lead and the at least one second lead is intermittently connected to the rear surface of each solar cell element.

Such an arrangement reduce a possibility that the leads 6 may be connected to the solar cell element 5 over a larger area than necessary and extra stresses may be generated.

In the solar cell module, preferably, at least one of the at least one first lead and the at least one second lead includes a connection portion that is connected to the rear surface of each solar cell element, and a non-connection portion that is not connected to the rear surface, and an angle between the connection portion and the non-connection portion is larger than 90 degrees.

Such a feature can further reduce a possibility that the leads 6 may be connected to the solar cell element 5 over a larger area than necessary and extra stresses may be generated.

In the solar cell module, preferably, at least one of the at least one first lead and the at least one second lead is a clad copper foil.

The lead 6 is, for example, a member prepared by coating a solder in thickness of about 20 μm to 70 μm on the surface of a low-resistance metal conductor made of, e.g., copper or aluminum with plating or dipping, and by cutting the coated conductor into an appropriate length. The lead 6 is made of a metal and hence has ductility. For example, a clad copper foil having a copper/Invar/copper structure may be used as the metal conductor. In that case, because the coefficient of thermal expansion of the lead 6 is closer to that of silicon, the warping of the solar cell element 5 is reduced.

In the solar cell module, preferably, each solar cell element is rectangular and the leads are parallel to one side of each solar cell element.

With such a feature, the magnitudes of warps can be made evener and the warps can be caused to occur in a specific direction.

In the solar cell module, preferably, the leads include a plurality of first leads, and the first leads are parallel to each other.

With such a feature, the magnitudes of warps can be made evener and the warps can be caused to occur in a specific direction.

In the solar cell module, preferably, the leads include a plurality of second leads, and the second leads are parallel to the first leads.

With such a feature, the magnitudes of warps can be made evener and the warps can be caused to occur in a specific direction.

In the solar cell module, preferably, the at least one first lead and the at least one second lead are alternately positioned.

With such a feature, the magnitudes of warps can be made evener and the warps can be caused to occur in a specific direction.

Further, the solar cell module is suitable for the case where adjacent two among the solar cell elements are electrically connected at the light receiving surface of one solar cell element and at the rear surface of the other by the leads. The reason is that, for example, when an area of the connected portion between the leads 6 and the solar cell element 5 differs between the light receiving surface and the rear surface, warping occurs convexly on one surface side.

In the solar cell module, preferably, the wavy shape includes a third projected portion projecting on the light receiving surface side of the first solar cell element.

For example, the solar cell module may be constructed such that, when the solar cell string 3 is viewed in a cross-section from a direction perpendicular to the array direction of the solar cell elements 5, the third projected portion of each solar cell element 5 is convexly formed on the side defining the light receiving surface 5b and the leads 6 are arranged following the convex form. Be it noted that the third projected portion is warped convexly on either side defining the light receiving surface 5b or the rear surface 5a depending on a difference in the area of the connected portion between the leads 6 and the solar cell 5.

In the solar cell module, preferably, the wavy shape includes a plurality of fourth projected portions projecting on the rear surface side.

In that case, two regions on both sides of the third projected portion projecting on the side defining the light receiving surface 5b are projected on the side defining the rear surface 5a and provide the fourth projected portions. Be it noted that the fourth projected portions are warped convexly on either side defining the light receiving surface 5b or the rear surface 5a depending on a difference in the area of the connected portion between the leads 6 and the solar cell 5.

In the solar cell module, preferably, the fourth projected portions are projected on the rear surface side farther away from both the end portions of the first solar cell element.

In that case, because the fourth projected portions projecting on the side defining the rear surface 5a are not flush with the both end portions 5e, the fourth projected portions 5d can provide the extreme points.

(Manufacturing Methods for Solar Cell Module)

### <First Manufacturing Method>

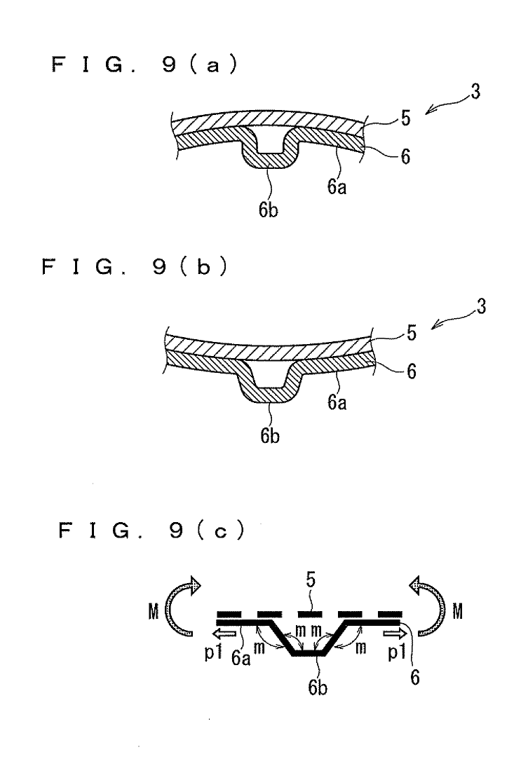

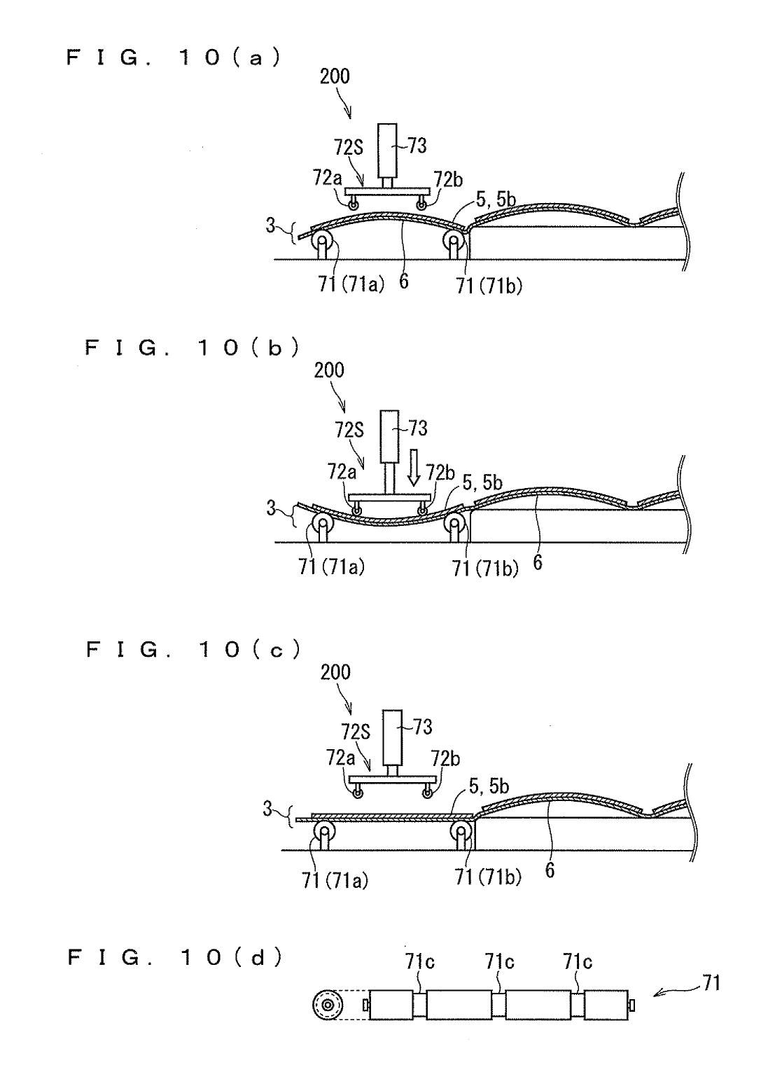

A first manufacturing method for the solar cell module X (Xa, Xb) according to the embodiment will be described with reference to FIGS. 7 and 8.

In a first step, as illustrated in FIG. 7(a), the solar cell elements 5 and the leads 6 are connected. In a state where the solar cell elements 5 are arrayed, the leads 6 are arranged to electrically connect the positive output electrode 53a of each solar cell element 5 and the negative output electrode 53b of another solar cell element 5 adjacent to the former. More specifically, in each solar cell element 5, different leads 6 (i.e., a first lead 61 and a second lead 62) are connected respectively to the output electrodes 53 having different polarities. Looking at a central one among three solar cell elements 5 illustrated in FIG. 7(a), for example, the positive output electrode 53a of the central solar cell element 5 is connected by the first lead 61 to the negative output electrode 53b of the solar cell element 5 at the right end, and the negative output electrode 53b of the central solar cell element 5 is connected by the second lead 62 to the positive output electrode 53a of the solar cell element 5 at the left end. The first lead 61 and the second lead 62 are arranged parallel to each other to ensure that both the leads will not be short-circuited upon contact therebetween. Preferably, at least one of the first lead 61 and the second lead 62 includes the concave portion (connection portion) 6a and the convex portion (non-connection portion) 6b as illustrated in FIG. 1.

The output electrode 53a or the output electrode 53b are connected to the lead 6 by using a solder. In more detail, the output electrode 53a or the output electrode 53b are connected to the lead 6 by applying a solder molten with heating to between the output electrode 53a or the output electrode 53b and the lead 6 to be connected by using a solder, and by cooling the applied solder.

In a stage after connecting the leads 6 as described above, the solar cell string 3a is often obtained in such a state that the solar cell elements 5 are each curved convexly on the side defining the second principal surface (light receiving surface) 5b, as illustrated in FIG. 7(b). The reason is that, because the lead 6 made of a metal has a larger coefficient of thermal expansion than the solar cell element 5 including the silicon substrate, the lead 6 is thermally contracted to a larger extent than the solar cell element 5 when the solder is cooled. If the solar cell string 3 including the thus-warped solar cell elements 5 is employed, as it is, in subsequent stacking and integrating steps, the solar cell module Xc illustrated in FIG. 6 is fabricated.

In this embodiment, therefore, prior to fabricating the solar cell module X, a second step is performed as a process of pressing the solar cell element 5 from the side defining the light receiving surface 5b and applying bending stresses with three-point bending to each of the solar cell elements 5, as illustrated in FIG. 8, for the purpose of canceling or reducing the warp of the solar cell elements 5 of the solar cell string 3.

Stated another way, the manufacturing method for the solar cell module includes a first step of electrically connecting, by leads, adjacent two among the solar cell elements each having the light receiving surface and the rear surface on the reverse side oppositely away from the light receiving surface, and a second step of applying a deformation force to act on each of the solar cell elements and projecting a partial region of each solar cell element on the lead side.

The above manufacturing method is based on the fact that, in particular, when the solar cell string is of the back contact type, the solar cell element 5 tends to warp and project on the side defining the light receiving surface 5b due to the difference in coefficient of thermal expansion between the lead 6 and the solar cell element 5.

In the manufacturing method for the solar cell module, preferably, the deformation force is a pressing force to press each solar cell element.

With such a feature, straightening of a warp can be most easily controlled.

In the manufacturing method for the solar cell module, preferably, the lead alternately includes a convex portion and a concave portion along a lengthwise direction of the lead, and the concave portion is connected to the solar cell element.

Such a feature can reduce the area of the connected portion between the lead 6 and the solar cell element 5 and can reduce the warping.

As illustrated in FIG. 8, a processing apparatus 100 used in the second step includes support members 71 (71a, 71b) supporting one of the solar cell elements 5 of the solar cell string 3, and a pressing member 72 pressing the one solar cell element 5. The pressing member 72 is coupled to an elevating apparatus 73, e.g., an air cylinder and is movable up and down with operation of the elevating apparatus 73. Bending stresses can be applied to the solar cell element 5 by pressing the solar cell element 5 from above with the pressing member 72 in a state where the solar cell element 5 is supported by the support members 71.

More specifically, in the second step, in the state where one of the solar cell elements 5 of the solar cell string 3 is supported by the support members 71, as illustrated in FIG. 8(a), with the light receiving surface 5b directed upwards, the convex portion of the light receiving surface 5b is pressed by the pressing member 72 as illustrated in FIG. 8(b). As a result, the solar cell element 5 is deformed into a bow-like flexed state where the solar cell element 5 is convex on the side including the leads 6 (i.e., the side defining the rear surface 5a).

In that deformed state, looking at a portion A in FIG. 8(b), as illustrated in FIG. 8(c), compressive stresses ac are generated in the solar cell element 5 that is positioned on the side above a neutral axis C, and tensile stresses at are generated in the lead 6 of which most part is positioned on the side under the neutral axis C. The compressive stresses σc and the tensile stresses σt increase at a position farther away from the neutral axis C. Stated another way, maximum compressive stress σcmax is generated in the light receiving surface 5b of the solar cell element 5, and maximum tensile stresses σtmax is generated in the surface of the lead 6.

Generally, the solar cell element 5 has high strength against compressive stresses, and it is less apt to undergo breakage, e.g., cracking, and to cause plastic strain. The reason is that because the solar cell element 5 is formed of a silicon substrate having brittleness and an affected layer is formed on the surface of the silicon substrate upon the silicon substrate being cut from an ingot, the solar cell element 5 is generally susceptible to the tensile stresses, but it is highly resistant against the compressive stresses. On the other hand, the lead 6 has a lower Young's modulus and a smaller cross-sectional area than the solar cell element 5, and it also has ductility. Accordingly, the lead 6 is more apt to cause plastic strain and to elongate with the tensile stresses.

Thus, when the solar cell string 3 is pressed in the state illustrated in FIG. 8(b), cracking of the solar cell element 5 subjected to primarily the compressive stresses is reduced, while the lead 6 subjected to the tensile stresses is plastically deformed in the tensile direction. As a result, in the solar cell element 5 after the pressing, the difference between thermal strains caused after the soldering in the solar cell element 5 and the lead 6 is reduced with leveling of the thermal strains, and the thermal stresses are reduced. By pressing all the solar cell elements 5 of the solar cell string 3 with the processing apparatus 100, the warp of each solar cell element is reduced and the solar cell string 3 having a relatively flattened shape, as illustrated in FIG. 1 and FIGS. 3 and 4, can be obtained. In particular, when the solar cell element 5 is pressed in the manner illustrated in FIG. 8 by using the processing apparatus 100, the solar cell string 3 in which the solar cell elements 5 have a wavy shape, as illustrated in FIGS. 3 and 4, can be more easily and positively formed. By properly setting the pressing conditions, the solar cell string 3, illustrated in FIG. 1, can also be formed without causing damages.

The solar cell module X in a wholly integrated form, illustrated in FIG. 1 or 4, is obtained through steps of stacking the above-described solar cell string 3 along with the light-transmissive base plate 1, the filling material 2a on the light receiving surface side, the filling material 2b on the non-light-receiving surface side, and the rear-surface protective member 4, heating and pressing a stacked assembly, and melting both the filling materials 2. In other words, the solar cell module X is realized in which the thermal stresses applied to the solder in the connected portion between the solar cell element 5 and the lead 6 are satisfactorily reduced, and in which the occurrence of creep deformation of the solder particularly under heat cycles and peeling-off at the connected portion cause by the deformation are reduced.

If the solar cell string 3a is stacked, as it is, along with the filling materials 2, etc., four corners of each solar cell element 5 tend to be caught with the filling materials 2, and loads tend to occur at the four corners. This is not desired in that, when the filling materials 2 are subjected to heating and pressing, cracking of the solar cell element 3 and bending of the lead 6 is more apt to occur.

Also, flattening the solar cell string 3a during the heating and pressing step of forming the integrated structure is not desired for the reason that, because the solar cell elements 5 are connected by the leads 6 and each solar cell element 5 is curved along the lengthwise direction of the lead 6, the solar cell string 3 is hard to be evenly strengthened flat and the solar cell element 5 is susceptible to cracking.

In contrast, with the manufacturing method according to this embodiment, since the solar cell module X is constituted by using the solar cell string 3 that has been previously flattened in the second step, the occurrence of cracks during the manufacturing process is satisfactorily reduced. Further, alignment accuracy in the widthwise direction of the solar cell string 3 during the stacking and integrating steps is maintained, and a variation in layout of the solar cell elements 5 inside the solar cell module X is reduced. As a result, an aesthetic impression in design of the solar cell module X is improved.

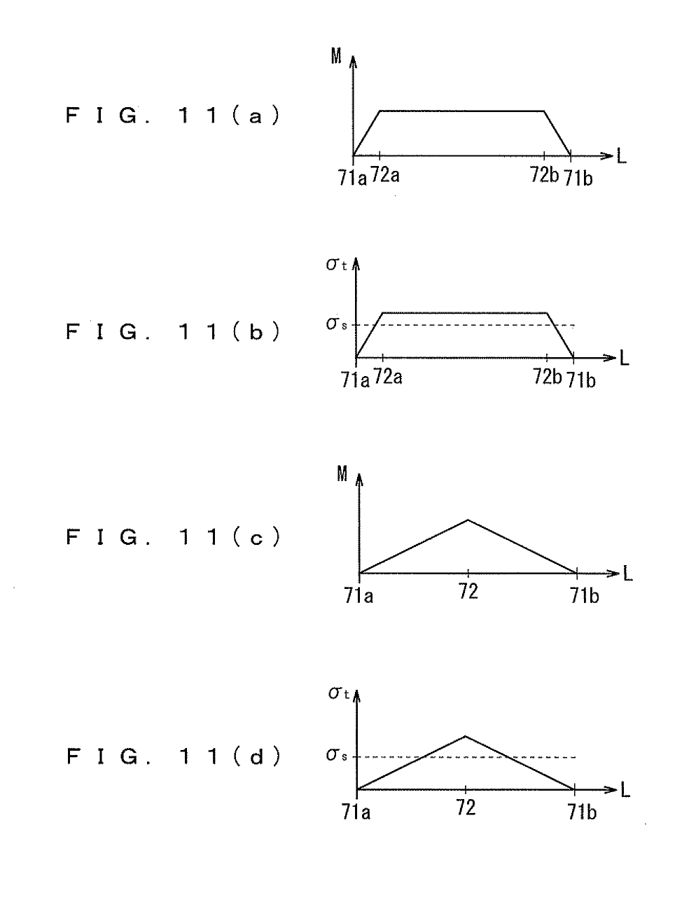

In the case using the lead 6 including the concave portion (connection portion) 6a and the convex portion (non-connection portion) 6b as illustrated in FIG. 9(a), when the solar cell string 3 fabricated in the first step is pressed in the second step, the solar cell elements 5 and the lead 6 is deformed as illustrated in FIG. 9(b). At that time, as illustrated in FIG. 9(c), tensile stresses p1 applied to the lead 6 act on the convex portion (non-connection portion) 6b as two couples of forces m (the sum of respective couples of forces m provides couple of forces M), which serve to extend bent corners. Stated another way, because the convex portion 6b is distorted by the couples of forces m, the lead 6 is elongated in a larger amount with a smaller force in the case using the lead 6 including the convex portion 6b than the case using the lead 6 that is uniformly long in the lengthwise direction thereof. Thus, the solar cell string 3 using the lead 6 including the convex portion 6b is more advantageous in that the bending stresses to be applied to the solar cell string 3 in the second step are reduced, whereby loads exerted on the solar cell element 5 become smaller and the occurrence of damages, e.g., cracks, is more surely reduced.

The support members 71 and the pressing member 72 are each preferably made of a material having a low friction coefficient, such as a fluorocarbon resin, whereby rotation and horizontal movement of the solar cell string 3 are facilitated when the bending stresses are applied to the solar cell string 3. In that case, when the solar cell element 5 is pressed, as illustrated in FIG. 8(b), from the side defining the light receiving surface 5b, the apparent length of the solar cell string 3 in the horizontal direction is shortened, and hence the tensile stresses generated in the solar cell string 3 are reduced. As a result, the occurrence of cracks in the solar cell element 5 is reduced.

In the second step of the manufacturing method for the solar cell module, preferably, the above-described deformation force is continuously applied to act on the solar cell elements, which are connected by the leads, from the solar cell element at one end to the solar cell element at the other end.

With such a feature, a stress distribution illustrated in FIG. 11 can be made flatter.

In the second step of the manufacturing method for the solar cell module, preferably, the above-described deformation force is applied to act on one of the solar cell elements in a state where the other solar cell elements than the one solar cell element are movable.

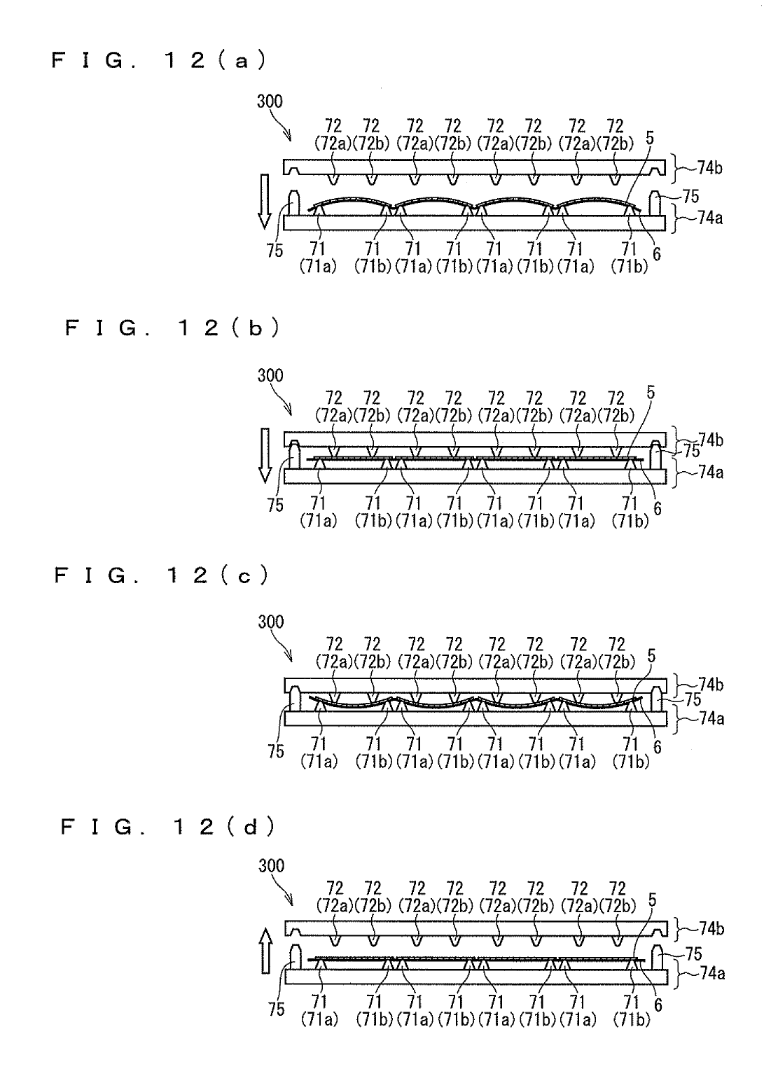

With such a feature, as illustrated in FIGS. 10, 13 and 14, even when the position of the one solar cell element 5 is shifted upon the pressing, excessive stresses can be avoided from being exerted on the leads 6 and the other solar cell elements 5 because the other solar cell elements 5 are movable.

In the second step of the manufacturing method for the solar cell module, preferably, in a state where one of the solar cell elements is supported at two fulcrums, the one solar cell element is pressed by using a rotatable pressing member from the reverse side with respect to the two fulcrums.

With such a feature, since the point of action is changed as the pressing of the solar cell element 5 progresses, the pressing member can be rotated following the change of the point of action.

In the manufacturing method for the solar cell module, preferably, the pressing member presses the one solar cell element in a portion thereof between the two fulcrums.

With such a feature, each of the solar cell elements 5 in the solar cell string 3a can exhibit flat stress distributions plotted in FIGS. 11(a) and 11(b).

Other examples of the manufacturing method for the solar cell module are as follows.

<Second Manufacturing Method>

A second manufacturing method for the solar cell module X according to the embodiment will be described below with reference to FIGS. 10 and 11.

The second manufacturing method differs from the first manufacturing method, which applies the bending stresses with the three-point bending, in that, in the second step, the solar cell elements 5 of the solar cell string 3 are each pressed at two positions from the side defining the light receiving surface 5b, whereby bending stresses are applied to the solar cell element 5 with four-point bending.

The four-point bending of the solar cell element 5 is performed by using a processing apparatus 200 that includes a pair of support members 71 (71a, 71b) and a pair of pressing members 72 (72a, 72b). The pair of pressing members 72a and 72b are mounted to a pressing member holder 72s, which is coupled to an elevating apparatus 73, with a predetermined spacing held between the pressing members 72a and 72b.

According to the second manufacturing method, in the second step, in the state where one of the solar cell elements 5 of the solar cell string 3 is supported by the support members 71 with the light receiving surface 5b directed upwards, as illustrated in FIG. 10(a), the solar cell element 5 is pressed by the two pressing members 72a and 72b. With the pressing, as illustrated in FIG. 10(b), the solar cell element 5 is deformed into a bow-like flexed state where the solar cell element 5 is convex on the side including the leads 6 (i.e., the side defining the rear surface 5a). After the pressing, the solar cell element 5 is flattened as illustrated in FIG. 10(c).

FIGS. 11(a) and 11(b) plot, respectively, a bending moment M applied to the solar cell element 5 and tensile stress at applied to the lead 6 when the solar cell element 5 is pressed with the four-point bending in the second manufacturing method. For comparison, FIGS. 11(c) and 11(d) plot, respectively, a bending moment M and tensile stress at applied when the solar cell element 5 is pressed in the first manufacturing method. In each of those plots, the horizontal axis represents positions of the related members by their symbols with the origin representing the position of the support member 71a. Further, FIGS. 11(b) and 11(d) plotting the tensile stresses σt indicate that plastic strain is generated in the lead 6 in a region where the tensile stress at exceeds yield stress as.

In the case of the three-point bending, as illustrated in FIG. 11(d), the tensile stress σt is maximized just at the position pressed by the pressing member 72. On the other hand, in the case of the four-point bending, as illustrated in FIG. 11(b), the tensile stress σt generated in the lead 6 has a substantially constant zone between the pressing member 72a and the pressing member 72b. Thus, the four-point bending can generate substantially constant plastic strain in the lead 6. As compared with the method using the three-point bending, concentration of stresses can be reduced and the warp can be substantially uniformly corrected over a wider region.

As illustrated in FIG. 10, rotatable rollers may be used as the support members 71 and the pressing members 72a and 72b. With the support members 71 and the pressing members 72a and 72b being rotatable, even when pressing forces applied from the pressing members 72a and 72b are increased and a frictional force between the solar cell string 3 and each of the support members 71 and the pressing members 72a and 72b is increased, the solar cell string 3 is easily movable upon flexing. Such an arrangement can more surely avoid the tensile stresses from being excessively applied to the solar cell element 5 during the pressing and can reduce the occurrence of cracks. Further, as illustrated in FIG. 10(d), grooves 71c may be each formed in a portion of the support member 71, which is positioned to face the lead 6, for the purpose of avoiding interference between the support member 71 and the lead 6. When the support member 71 includes the grooves 71c, the leads 6 and the support member 71 are not contacted with each other even in the state where the pressing forces are applied to the solar cell element 5 by the pressing members 72a and 72b. Accordingly, concentration of loads into the vicinity of the connected portions between the solar cell element 5 and the leads 6 can be reduced.

By pressing all the solar cell elements 5 of the solar cell string 3 by using the processing apparatus 200, the second manufacturing method can also reduce the warping of each solar cell element 5 and provide the flattened solar cell string 3. While FIG. 10(c) illustrates the case where the solar cell element 5 are each entirely flat as in the case of FIG. 1 in the horizontal direction when viewed on the drawing, the solar cell string 3 in which the solar cell elements 5 have a wavy shape, as illustrated in FIGS. 3 and 4, can also be more easily and positively formed, as with the first manufacturing method, when the solar cell elements 5 are pressed in the manner illustrated in FIG. 10 by using the processing apparatus 200.

<Third Manufacturing Method>

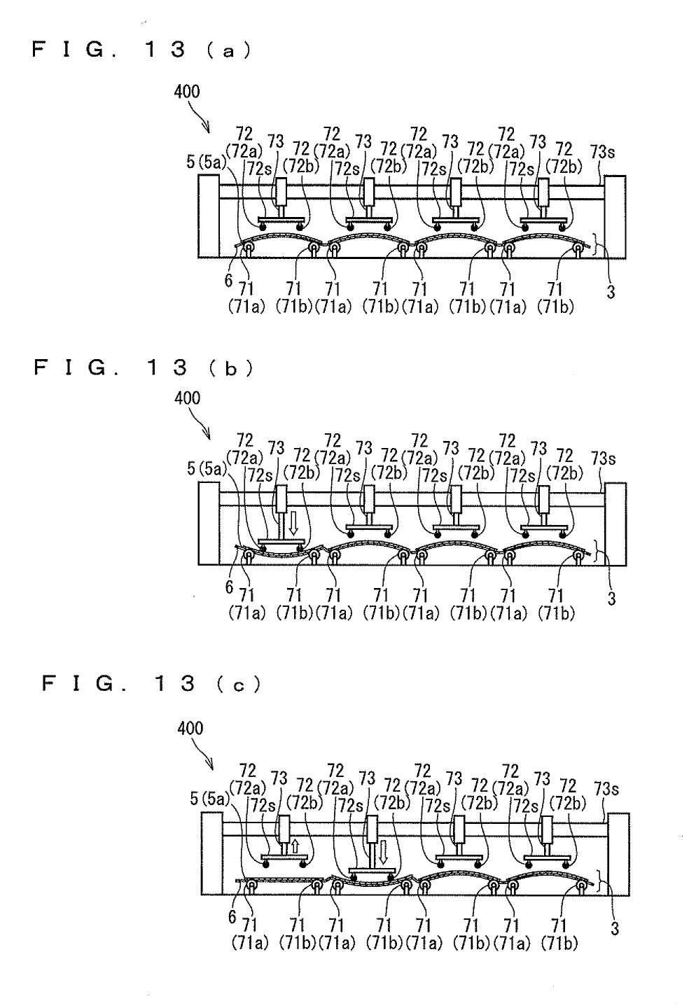

A third manufacturing method for the solar cell module X according to the embodiment will be described below with reference to FIG. 12.

The third manufacturing method differs from the second manufacturing method, in which the bending stresses with the four-point bending are applied to the individual solar cell elements 5 one by one, in that, in the second step, the bending stresses with the four-point bending are applied to all the individual solar cell elements 5 substantially at the same time by performing the four-point bending on all the solar cell elements 5 of the solar cell string 3 substantially at the same time.

The four-point bending in the third manufacturing method is performed by using a processing apparatus 300 that includes a plate 74a provided with a plurality of support members 71 (71a, 71b) and a plate 74b provided with a plurality of pressing members 72 (72a, 72b). The plate 74b is movable up and down by an elevating apparatus (not shown). In the processing apparatus 300, the individual solar cell elements 5 of the solar cell string 3 are each supported by one pair of the support members 71 (71a, 71b), and each solar cell element 5 is pressed by one pair of the pressing members 72 (72a, 72b) with a descent of the plate 74b.

According to the third manufacturing method, in the second step, in the state where the solar cell elements 5 of the solar cell string 3 are each supported, as illustrated in FIG. 12(a), by the corresponding support members 71 with the light receiving surface 5b directed upwards, each solar cell element 5 is pressed by the corresponding two pressing members 72a and 72b, as illustrated in FIG. 12(b). With the pressing, as illustrated in FIG. 12(c), all the solar cell elements 5 are deformed into a bow-like flexed state where each solar cell element 5 is convex on the side including the leads 6 (i.e., the side defining the rear surface 5a). After the pressing, all the solar cell elements 5 are flattened as illustrated in FIG. 12(d).

Thus, the third manufacturing method can also reduce the warping of each solar cell element 5 and provide the flattened solar cell string 3. While FIG. 12(d) illustrates the case where the solar cell elements 5 are each entirely flat as in the case of FIG. 1 in the horizontal direction when viewed on the drawing, the solar cell string 3 in which the solar cell elements 5 have a wavy shape, as illustrated in FIGS. 3 and 4, can also be more easily and positively formed, as with the first manufacturing method, when the solar cell elements 5 are pressed in the manner illustrated in FIG. 12 by using the processing apparatus 300.

In addition, with the third manufacturing method, since the bending stresses are applied to all the solar cell elements 5 of the solar cell string 3 at a time, a tact time can be shortened as compared with that in the second manufacturing method.

As illustrated in FIG. 12, spacers 75 for specifying the spacing between the plate 74a and the plate 74b may be provided on the plate 74a. With the provision of the spacers 74, a range where the pressing members 72 can be moved down is limited by the spacers 75, and the pressing forces applied to the solar cell elements 5 are limited within a certain range. Thus, the provision of the spacers 75 on the plate 74a is advantageous from the viewpoint of proper management of the pressing forces.

Further, in the third manufacturing method, in a state where the individual solar cell elements 5 of the solar cell string 3 are held in the flexed state illustrated in FIG. 12(c), thermal stresses may be applied to the solar cell string 3 by cooling the solar cell string 3 to temperature not higher than 0° C. In that case, the thermal stresses act as tensile stresses on the leads 6 having the larger coefficient of thermal expansion than the solar cell elements 5. Because the thermal stresses act as tensile stresses in addition to the tensile stresses that are mechanically applied by the pressing members 72, the leads 6 are subjected to larger plastic strain than that in the case where the tensile stresses are applied just mechanically. As a result, the warping of each solar cell element 5 can be more effectively reduced.

Since the thermal stresses due to the cooling are generated over the entire joining interface between the solar cell element 5 and the lead 6, stress concentration is less likely to occur.

The method including the cooling can give larger elongation to the lead 6 as compared with the method not including the cooling. Therefore, when the difference between thermal strains in the solar cell element 5 and the lead 6 after the first step is relatively large and the solar cell element 5 is warped to a larger extent, the method including the cooling is especially effective in reducing that difference with leveling of the thermal strains.

<Fourth Manufacturing Method>

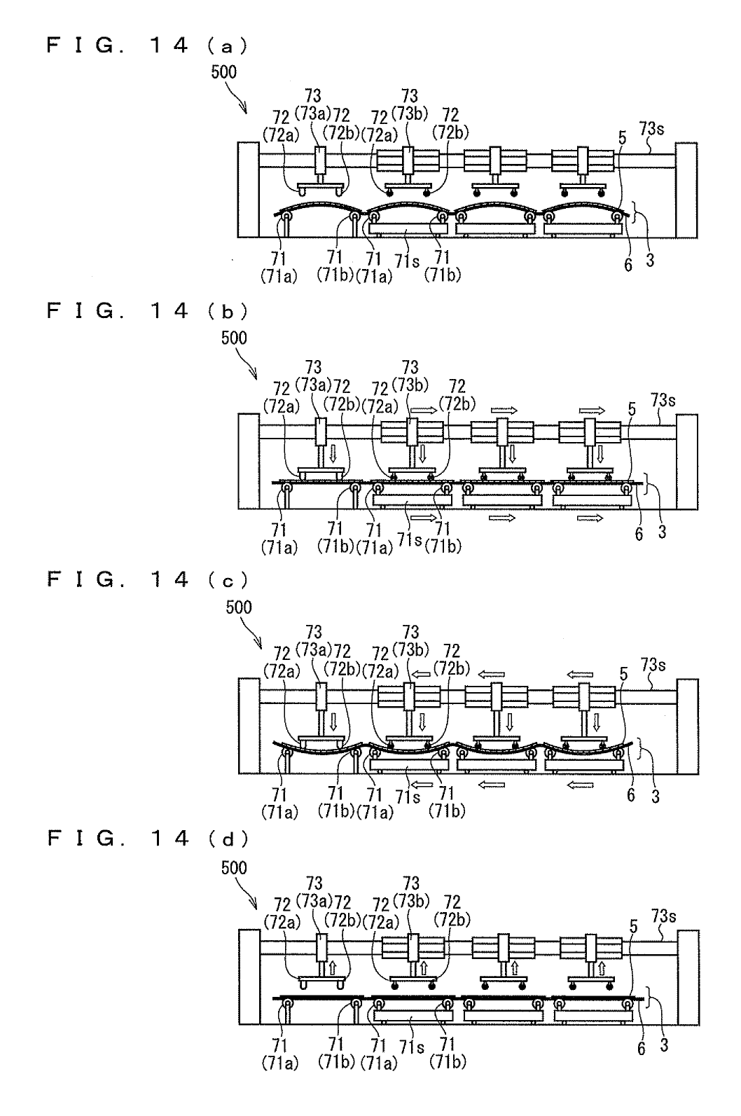

A fourth manufacturing method for the solar cell module X according to the embodiment will be described below with reference to FIG. 13.

The fourth manufacturing method is common to the second manufacturing method in the first step and in that the fourth-point bending is successively performed in the second step on the individual solar cell elements 5 of the solar cell string 3 one by one, but it differs from the second manufacturing method in that the four-point bending of the individual solar cell elements 5 is performed by using different support members 71 and different pressing members 72, while the solar cell string 3 is held stationary.

The four-point bending in the fourth manufacturing method is performed by using a processing apparatus 400 that includes a plurality of support members 71 (each including 71a, 71b) and a plurality of pressing members 72 (each including 72a, 72b). In the processing apparatus 400, the individual solar cell elements 5 of the solar cell string 3 are each supported by one pair of support members 71 (71a, 71b), and each solar cell element 5 is pressed by one pair of pressing members 72a and 72b. The pair of pressing members 72a and 72b are mounted to a pressing member holder 72s, which is coupled to an elevating apparatus 73, with a predetermined spacing held between the pressing members 72a and 72b. Individual elevating apparatuses 73 are held by an elevating apparatus holder 73s.

According to the fourth manufacturing method, in the second step, in the state where the individual solar cell elements 5 of the solar cell string 3 are each supported by the corresponding support member 71, as illustrated in FIG. 13(a), with the second principal surface 5b directed upwards, the projected portion of the light receiving surface 5b of the solar cell element 5 (5a) at the leftmost end is first pressed by the pressing member 72, as illustrated in FIG. 13(b). With the pressing, the solar cell element 5a is deformed into a bow-like flexed state where the solar cell element 5a is convex on the side including the leads 6 (i.e., the side defining the first principal surface 5a). After deforming the solar cell element 5a, the solar cell element 5 (5b) adjacent to the solar cell element 5a is pressed by the corresponding pressing member 72 in a similar manner, as illustrated in FIG. 13(c). Thereafter, the pressing is successively performed on the solar cell element 5 (5c) adjacent to the solar cell element 5b, the solar cell element 5 adjacent to the solar cell element 5c, and so on.

Thus, the fourth manufacturing method can also reduce the warping of each solar cell element 5 and provide the flattened solar cell string 3. While FIG. 13(c) illustrates the case where the solar cell element 5 after the four-point bending is entirely flat as in the case of FIG. 1 in the horizontal direction when viewed on the drawing, the solar cell string 3 in which each solar cell element 5 has a wavy shape, as illustrated in FIGS. 3 and 4, can also be more easily and positively formed, as with the first manufacturing method, when the solar cell elements 5 are successively pressed in the manner illustrated in FIG. 13 by using the processing apparatus 400.

In the third manufacturing method described before, because the individual solar cell elements 5 of the solar cell string 3 are pressed substantially at the same time, the entirety of the solar cell string 3 is smoothly moved to be adapted for apparent expansion and contraction in the horizontal direction upon flexing of the solar cell elements 5. However, as the length of the solar cell string 3 increases, larger frictional forces are generated and the solar cell string 3 is less easy to move. In such a case, undesired stresses may be locally applied to the solar cell element 5 and the leads 6.

In contrast, according to the fourth manufacturing method, because of the solar cell elements 5 being successively pressed, when each solar cell element 5 is pressed, the solar cell elements 5 adjacent to the relevant one are freely movable on the support members 71. Therefore, even when the length of the solar cell element 5 in the horizontal direction is changed during the pressing, compressive stresses or tensile stresses generated in the leads 6 connecting the relevant solar cell element 5 and the adjacent solar cell element 5 are reduced. As a result, the occurrence of cracks in the solar cell element 5 and the peeling-off at the connection portions of the leads 6 can be reduced.

While the pressing members 72 are provided respectively corresponding to the solar cell elements 5 in the processing apparatus 400 illustrated in FIG. 13, such an arrangement is not essential. The processing apparatus 400 may be modified such that the individual solar cell elements 5 are successively pressed and subjected to the bending stresses by moving one pressing member 72 in the horizontal direction with the solar cell string 3 held in the stationary state.

<Fifth Manufacturing Method>

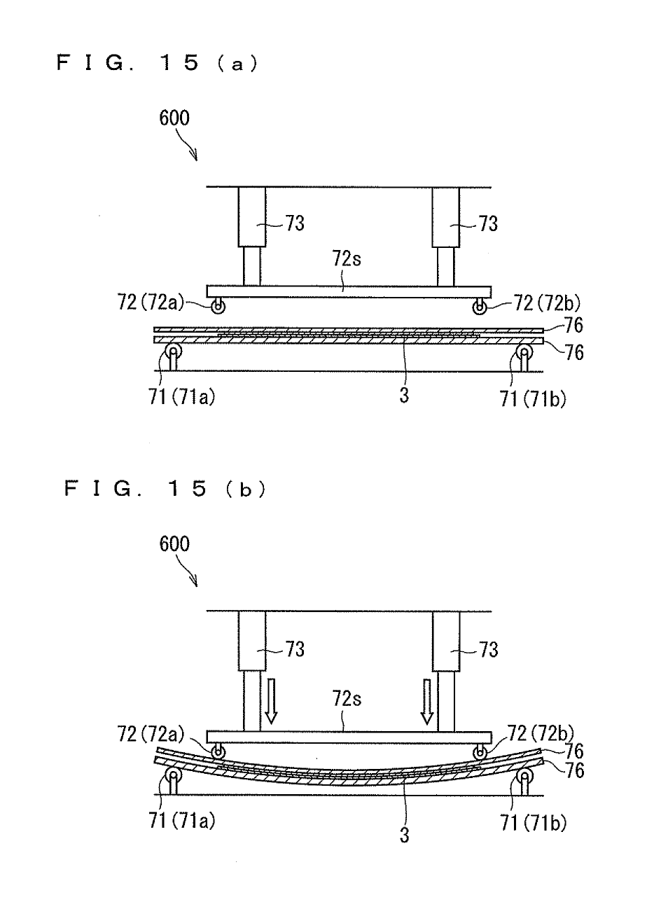

A fifth manufacturing method for the solar cell module X according to the embodiment will be described below with reference to FIG. 14.

The fifth manufacturing method is common to the fourth manufacturing method in the first step and in that the fourth-point bending is performed in the second step on the individual solar cell elements 5 of the solar cell string 3 by using different support members 71 and different pressing members 72, but it differs from the fourth manufacturing method in performing the four-point pressing of the individual solar cell elements 5 at the same time and using the support members 71 and the pressing members 72, which are movable in the state where the individual solar cell elements 5 are supported and pressed.

The four-point bending in the fifth manufacturing method is performed by using a processing apparatus 500 that includes, as in the processing apparatus 400, a plurality of support members 71 (each including 71a, 71b) and a plurality of pressing members 72 (each including 72a, 72b). More specifically, the individual solar cell elements 5 of the solar cell string 3 are each supported by one pair of support members 71 (71a, 71b), and each solar cell element 5 is pressed by one pair of pressing members 72a and 72b. In the processing apparatus 500, however, the support member 71 supporting the solar cell element 5 at the leftmost end of the solar cell string 3 and an elevating apparatus 73 (73a) for moving, through a pressing member 72s, up and down the pressing member 72, which presses the solar cell element 5 at the leftmost end of the solar cell string 3, are provided fixedly in the horizontal direction, whereas the support members 71 supporting the other solar cell elements 5 are disposed respectively on horizontally movable units 71s and elevating apparatuses 73 (73b) for moving up and down the pressing members 72, which press those other solar cell elements 5, are also movable in the horizontal direction.

According to the fifth manufacturing method, in the second step, in the state where the individual solar cell elements 5 of the solar cell string 3 are each supported by the corresponding support member 71, as illustrated in FIG. 14(a), with the light receiving surface 5b directed upwards, the projected portion of the light receiving surface 5b of each solar cell element 5 is first pressed by the corresponding pressing member 72, as illustrated in FIG. 14(b). At that time, because the solar cell string 3 is temporarily flattened, the solar cell string 3 is apparently elongated in the horizontal direction. Responsively, the movable units 71s for the support members 71 and the elevating apparatuses 73b are moved. Therefore, the support members 71 and the pressing members 72 other than those at the leftmost end are moved following the elongation of the solar cell string 3 while the solar cell elements 5 are deformed with the four-point bending. In other words, the support members 71 and the pressing members 72 are moved in a direction in which the center-to-center interval between the adjacent solar cell elements 5 is increased. Thus, excessive compressive stresses are more surely avoided from being applied to the solar cell elements 5 and the leads 6 with the elongation of the solar cell string 3.

Subsequently, each solar cell element 5a is deformed into a bow-like flexed state where the solar cell element is convex on the side including the leads 6 (i.e., the side defining the rear surface 5a), as illustrated in FIG. 14(c). At that time, because the solar cell string 3 is apparently contracted in the horizontal direction, the support members 71 and the pressing members 72 other than those at the leftmost end are now moved following the contraction of the solar cell string 3 contrary to the above-described step of FIG. 14(b). In other words, the support members 71 and the pressing members 72 are moved in a direction in which the center-to-center interval between the adjacent solar cell elements 5 is reduced. Thus, excessive compressive stresses are more surely avoided from being applied to the solar cell elements 5 and the leads 6 with the contraction of the solar cell string 3.

The fifth manufacturing method can also reduce the warping of each solar cell element 5 and provide the flattened solar cell string 3. While FIG. 14(d) illustrates the case where the solar cell element 5 is entirely flat as in the case of FIG. 1 in the horizontal direction when viewed on the drawing, the solar cell string 3 in which each solar cell element 5 has a wavy shape, as illustrated in FIGS. 3 and 4, can also be more easily and positively formed, as with the first manufacturing method, when the solar cell elements 5 are pressed in the manner illustrated in FIG. 14 by using the processing apparatus 500.

Further, according to the fifth manufacturing method, since the compressive forces and the tensile forces generated in the solar cell elements 5 and the leads 6 can be reduced, the individual solar cell elements 5 of the solar cell string 3 can be efficiently pressed while peeling-off at the connected portions between the solar cell elements 5 and the leads 6 is reduced. Hence, the fifth manufacturing method can increase the yield of the solar cell modules on one hand, and can shorten a tact time and improve production efficiency on the other hand.

<Method of Verifying Shape of Solar Cell Element in Solar Cell Module>

The fact that, in the solar cell module X according to the embodiment of the present invention, the individual solar cell elements 5 of the solar cell string 3 have a wavy curved shape (curvature) along the array direction of the solar cell elements 5 can be verified by disassembling an actual product. The verification can be performed, for example, by dissolving the filling materials 2 in the solar cell module X and taking out the solar cell string 3 in accordance with a method described below.

First, a notch is cut in the rear-surface protective member 4. The cutting may be manually performed by using, e.g., a cutter, a disk-shaped cutter, or a laser cutter. However, it is preferable to employ an automatic tool in the form of a disk-shaped cutter, a disk-shaped whetstone, or a laser cutter. Using the automatic tool is effective in expediting infiltration of an organic solvent and shortening a recovery time of the solar cell string 3.

Next, an organic solvent capable of dissolving the filling materials 2 is filled in a tank that has a size at least enough to receive the entirety of the solar cell module X lying in a horizontal posture. The solar cell module X is then placed in the tank and immersed in the organic solvent. The organic solvent can be prepared as d- limonene, xylene, or toluene. The organic solvent may be held at the room temperature, but it is preferably heated to 80° C. to 100° C. from the viewpoint of expediting the dissolution of the filling materials 2 and shortening a disassembly time. The filling materials 2 are dissolved by immersing the solar cell module X in the organic solvent for about 24 hours when the organic solvent is held at the room temperature, or for about 1 to 2 hours when the organic solvent is heated to 80° to 100° C. After the dissolution of the filling materials 2, the solar cell string 3 can be taken out from the tank.

The shape of the solar cell string 3 taken out as described above can be measured by using, e.g., a device that measures the shape of a three-dimensional curved surface with a laser. Alternatively, the shape of the solar cell string 3 may be measured by placing the solar cell string 3 on a surface plate, and by measuring and plotting floating distances from the surface plate with a vernier caliper. With one of those methods, it is possible to specify the shape of the solar cell string 3 and to confirm that the solar cell element 5 has the wavy shape described above in the embodiment.

As an alternative, the warped shapes of the solar cell element 5 and the solar cell string 3 can also be specified by using an optical observation device, e.g., an optical microscope, introducing and focusing observation light at each of plural positions on the light receiving surface 5b of the solar cell element 5 from the outside of the solar cell module X, measuring the focal depth at each of the plural points, and plotting spatial change of the focal depth.

<Modifications>

### (Case of Both-Side Contact Type)

The foregoing embodiments have been described in connection with the case using the solar cell element of back contact type. However, the advantageous effects of the present invention can also be obtained when applied to a solar cell module of both-side contact type, insofar as the solar cell element becomes convex on the side including the second principal surface, i.e., the light receiving surface side, after connecting the leads. For example, the solar cell element takes such a convex shape when, in the solar cell module of both-side contact type, an area of a conductor connected portion on the first principal surface of the solar cell element is larger than an area of a conductor connected portion on the second principal surface thereof.

When applied to the solar cell module of both-side contact type, the present invention can also provide similar advantageous effects to those in the foregoing embodiments by employing a solar cell string in which the solar cell elements are flattened as illustrated in FIGS. 1 to 4. Further, such a solar cell string can be formed in a similar way to that in the foregoing embodiments by using one of the above-described manufacturing methods.

(First Modification of Manufacturing Method)

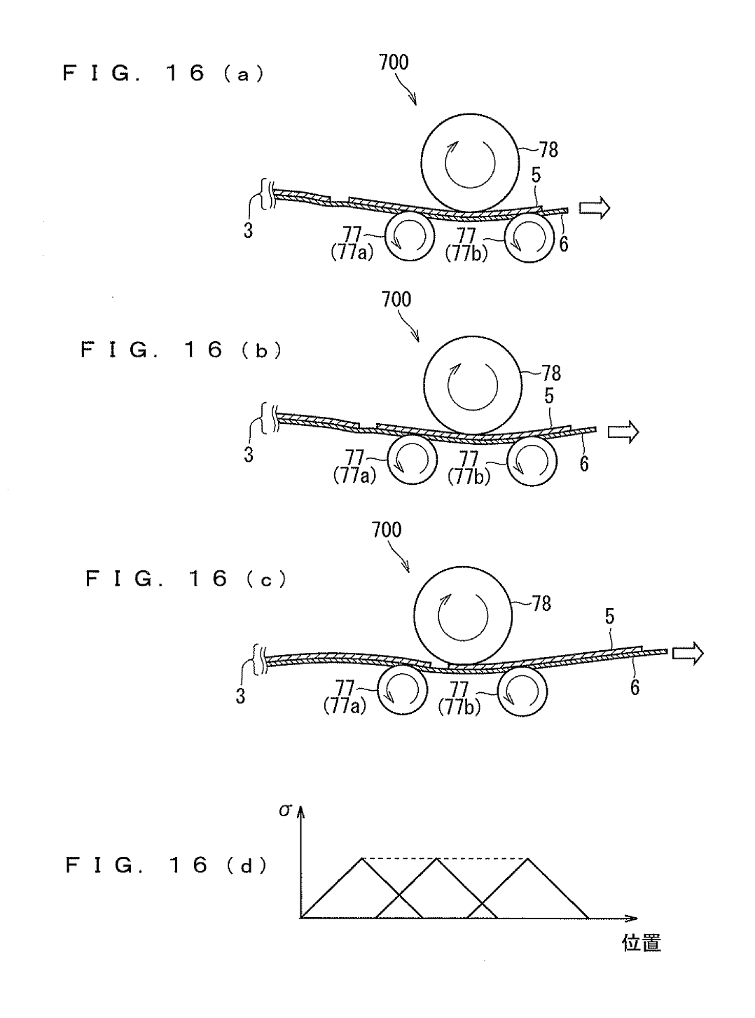

In the foregoing embodiments, the individual solar cell elements 5 of the solar cell string 3 are separately deformed in the second step of the manufacturing method for the solar cell module X. However, flattening of the solar cell string 3 can also be realized by deforming the entirety of the solar cell string 3 instead of separately deforming the individual solar cell elements 5. A method of deforming the entirety of the solar cell string 3 will be described as a first modification with reference to FIG. 15.

The first modification employs a processing apparatus 600 including a pair of support members 71 (71a, 71b), a pair of pressing members 72 (72a, 72b) disposed on a pressing member holder 72s, which is coupled to an elevating apparatus 73, with a predetermined spacing held between the pressing members 72, and a pair of plates 76 (76a, 76b) sandwiching the solar cell string 3 between them.

For example, an aluminum plate can be used as each of the plates 74. Stainless steel, spring steel, phosphor bronze, etc. are also suitable materials for the plates 74 because they have wide elastic ranges and are less fatigued even when subjected to repetitive bending deformations.

In this modification, in the state where the solar cell string 3 sandwiched between the pair of plates 76 is supported by the support members 71, as illustrated in FIG. 15(a), with the light receiving surface 5b directed upwards, the solar cell string 3 is pressed by the two pressing members 72a and 72b, as illustrated in FIG. 15(b). As a result, the solar cell string 3 is flattened.

According to the first modification, since the solar cell string 3 is pressed in the state where it is entirely sandwiched between the pair of plates 74, stress concentration is less apt to occur in the solar cell element 5, and the occurrence of cracks upon application of the bending stresses is reduced. Further, since the bending stresses are applied to the entirety of the solar cell string 3 at a time, workability is improved in comparison with the method of individually pressing the solar cell elements 5.

Moreover, when, as illustrated in FIG. 15(b), the solar cell string 3 is positioned between the pressing member 72a and the pressing member 72b and is subjected to four-point bending, substantially constant bending stresses are applied to the entirety of the solar cell string 3. Therefore, the substantially constant bending stresses are applied to all the leads 6 and cause plastic strains therein. Thus, warping is substantially uniformly reduced throughout the solar cell string 3, and the solar cell string 3 is flattened in its entirety. In other words, according to this modification, the leads 6 are more surely avoided from undergoing locally biased plastic strains, and loads exerted on the solar cell elements 5 are reduced. As a result, the solar cell string 3 having the shape illustrated in FIG. 1 can be satisfactorily obtained.

(Second Modification of Manufacturing Method)

The method of applying the bending stresses to the solar cell string 3 and flattening the same in the second step of the manufacturing method for the solar cell module X is not limited to the ones described in the foregoing embodiments. A method of flattening the solar cell string 3 in a different way from those in the foregoing embodiments will be described as a second modification with reference to FIG. 16.

In this modification, the solar cell string 3 is flattened by pressing the solar cell element 5 with rotating members. As illustrated in FIG. 16(a), the second modification employs a processing apparatus 700 including a pair of support rollers 77 (77a, 77b) and a pressing roller 78.

In more detail, as illustrated in FIG. 16(a), the solar cell string 3 arranged with the second principal surface 5b directed upwards is conveyed while it is supported by the rotating support rollers 77 from below. The solar cell string 3 under conveyance is pressed by the pressing roller 78, which is also rotatable and which is disposed on the upper side. Thus, the solar cell string 3 is conveyed while bending stresses with three-point bending are applied to the solar cell string 3, as successively illustrated in FIGS. 16(a), 16(b) and 16(c). During the conveyance, as illustrated in FIG. 16(d), a position where tensile stress applied to the lead 6 is maximized is moved with the movement of the solar cell string 3. Hence, substantially constant plastic strains are caused in the leads 6 over a wide region of the solar cell string 3. As a result, a warp of the solar cell element 5 is uniformly reduced over the wide region of the solar cell string 3. Stated another way, loads exerted on the solar cell element 5 can be kept smaller, and the solar cell string 3 can be uniformly flattened over the wide region.

According to the second modification, since the bending stresses are applied to the solar cell string 3 while the solar cell string 3 is conveyed in the state held between the support rollers 76 and the pressing roller 77, positioning of the solar cell string 3 in its lengthwise direction is not required unlike the foregoing embodiments in which the bending stresses are applied to the solar cell string 3 in the standstill state. Further, since the solar cell string 3 to be further processed can be easily supplied to the next step, the second modification is suitable for a manufacturing line in which production steps are linearly arranged.

Additionally, mechanical impacts exerted on the solar cell elements 5 and the leads 6 can be reduced by deforming them with the processing apparatus 700 in a state where the solar cell string 3 is sandwiched between soft sheet-like members made of, e.g., urethane rubber or EPDM.

1. A solar cell module comprising:
a plurality of solar cell elements each including a light receiving surface and a rear surface positioned on a reverse side oppositely away from the light receiving surface; and
leads connecting one of the solar cell elements and another adjacent solar cell element, and including a connection portion connected to one surface of the one solar cell element,
wherein adjacent two among the solar cell elements are electrically connected at the rear surfaces thereof by the leads,
wherein at least one of the solar cell elements has a wavy shape in a lengthwise direction of the connection portion, and
wherein at least one of the leads has a wavy shape corresponding to the wavy shape of the at least one of the solar cell elements in the lengthwise direction of the connection portion.

2-5. (canceled)

6. The solar cell module according to any claim 1, wherein the leads include at least one first lead and at least one second lead exhibiting polarity that is opposite to polarity of the at least one first lead with respect to each of the solar cell elements.

7. The solar cell module according to claim 6, wherein the at least one first lead and the at least one second lead are parallel to each other.

8. The solar cell module according to claim 6, wherein at least one of the at least one first lead and the at least one second lead is intermittently connected to the rear surface of each of the solar cell elements.

9. The solar cell module according to claim 6, wherein at least one of the at least one first lead and the at least one second lead includes the connection portion that is connected to the rear surface of each of the solar cell elements, and a non-connection portion that is not connected to the rear surface, and wherein an angle between the connection portion and the non-connection portion is larger than 90 degrees.

10. The solar cell module according to claim 1, wherein at least one of the at least one first lead and the at least one second lead is a clad copper foil.

11. The solar cell module according to claim 1, wherein each of the solar cell elements is rectangular and the leads are parallel to one side of each solar cell element.

12. The solar cell module according to claim 1, wherein the leads include a plurality of first leads, and the first leads are parallel to each other.

13. The solar cell module according to claim 12, wherein the leads include a plurality of second leads, and the second leads are parallel to the first leads.

14. The solar cell module according to claim 6, wherein the at least one first lead and the at least one second lead are alternately positioned.

15. (canceled)

16. The solar cell module according to claim 1, wherein the wavy shape of the at least one of the solar cell elements includes a plurality of projected portions projecting on a light receiving surface side of the at least one of the solar cell elements.

17. The solar cell module according to claim 1, wherein the wavy shape of the at least one of the solar cell elements includes a plurality of projected portions projecting on a rear surface side farther away from both end portions of the at least one of the solar cell elements.

18. (canceled)

19. A method of manufacturing a solar cell module, the method comprising:
a first step of electrically connecting, by a lead, adjacent two among a plurality of solar cell elements each including a light receiving surface and a rear surface on a reverse side oppositely away from the light receiving surface; and
a second step of applying a deformation force to act on each of the solar cell elements and projecting a partial region of each solar cell element on a lead side.

20. The method of manufacturing the solar cell module according to claim 19, wherein the deformation force is a pressing force to press each of the solar cell elements.

21. The method of manufacturing the solar cell module according to claim 19, wherein the lead alternately includes a convex portion and a concave portion along a lengthwise direction of the lead, and the concave portion is connected to each of the solar cell elements.

22. The method of manufacturing the solar cell module according to claim 19, wherein, in the second step, the deformation force is continuously applied to act on the solar cell elements, which are connected by the lead, from the solar cell element at one end to the solar cell element at the other end.

23. The method of manufacturing the solar cell module according to claim 19, wherein, in the second step, the deformation force is applied to act on one of the solar cell elements in a state where the other solar cell elements than the one solar cell element are movable.

24. The method of manufacturing the solar cell module according to claim 19, wherein, in the second step, in a state where one of the solar cell elements is supported at two fulcrums, the one solar cell element is pressed by using a rotatable pressing member from a reverse side with respect to the two fulcrums.

25. The method of manufacturing the solar cell module according to claim 24, wherein the pressing member presses the one solar cell element in a portion thereof between the two fulcrums.

26. The solar cell module according to claim 16, wherein the projected portions are projected on the light receiving surface side farther away from both end portions of the at least one of the solar cell elements.
